(19) United States
(12) Patent Application Publication
(10) Pub. No.: US 2006/0262481 A1
(43) Pub. Date: Nov. 23, 2006

(54) Film carrier tape with capacitor circuit and method for manufacturing the same, and surface-mounted film carrier tape with capacitor circuit and method for manufacturing the same

(75) Inventor: Yasuaki Mashiko, Ageo-shi (JP)

Correspondence Address: THE WEBB LAW FIRM, P.C., 700 KOPPERS BUILDING, 436 SEVENTH AVENUE, PITTSBURGH, PA, 15219, US

(73) Assignee: Mitsui Mining and Smelting Co., Ltd., Shinagawa-ku (JP)

(21) Appl. No.: 11/436,697

(22) Filed: May 18, 2006

(30) Foreign Application Priority Data
May 20, 2005 (JP) 2005-148765

(51) Int. Cl. H01G 4/228; H01G 4/10; H01G 4/06

(52) U.S. Cl. 361/306.2; 361/322; 361/311; 361/306.1

(57) ABSTRACT

The present invention provides a manufacturing method capable of mass production of a thin film decoupling capacitor provided with a capacitor circuit on the surface of a film tape carrier form of a polyimide resin or the like. For the purpose of achieving the above described object, there is provided a film carrier tape with a capacitor circuit, including a wiring pattern on the surface of a resin film including a plurality of sprocket holes on each of the two edges, wherein the resin film includes solder ball land holes and the wiring pattern includes a capacitor circuit having a structure in which a dielectric layer is disposed between an upper electrode and a lower electrode. As the method for manufacturing the aforementioned film carrier tape, there is provided such a method for semicontinuously manufacturing the film carrier tape concerned in the state of tape as applied to manufacturing conventional TAB products.

### BACKGROUND OF THE INVENTION

1. Field of the Invention

The present invention relates to a film carrier tape with a capacitor circuit and a method for manufacturing the film carrier tape with a capacitor circuit, and a surface-mounted film carrier tape with a capacitor circuit and a method for manufacturing the surface-mounted film carrier tape with a capacitor circuit.

2. Description of the Related Art

In these years, mobile electronic devices represented by laptop personal computers, cellular phones and the like have been remarkably developed, and these devices are required to be reduced in size, thickness and weight, and also to have high and multiple functions. Accordingly, packages to be built in these electronic information devices are required to permit high density mounting and also to achieve rapid and reliable signal transfer as fundamental capabilities.

A GHz clock frequency is applied to the arithmetic processing in the central processing unit (LSI) mounted in the aforementioned package, and reduction of the switching noises is required. Furthermore, such a package is required to be reduced in noises generally as a package article. For the purpose of solving such problems, as disclosed in Non-patent Document 1, there have been made attempts to lower the impedance in the high frequency bands by reducing the equivalent series inductance and by reducing the loop impedance through making the distances between the capacitors and the mounted components as small as possible.

The aforementioned decoupling capacitor elements have hitherto been formed, as disclosed in Non-patent Document 1, on the surface of rigid substrates such as silicon substrates and glass substrates so as to be often mounted on the surface of circuit substrates or embedded in the substrates. However, these articles using rigid substrates lack flexibility, leading to the lack of crack resistance and handlability as seen in machining.

For the purpose of solving such problems, as disclosed in Non-patent Documents 2 and 3, it is proposed that decoupling capacitor elements are formed on the surface of polyimide resin substrates excellent in flexibility.

[Non-patent Document 1] “Electric Properties of a Package with a Built-in Thin Capacitor,” Proceedings of the 11th symposium on Microjoining and Assembly Technology in Electronics, pp. 441-444 (Feb. 3, 2005).

[Non-patent Document 2] “SrTiO₃ Thin Film Decoupling Capacitor on Polyimide Film,” Proceedings of the 19th Electronics Packaging Conference, pp. 195-196, 18A-10 (Mar. 3, 2005).

[Non-patent Document 3] “Integrated Thin Film Capacitors in Organic Laminates for Systems in Package Applications,” ICEP 2005 Proceedings, pp. 152-155.

### SUMMARY OF THE INVENTION

Any of the methods disclosed in Non-patent Documents 2 and 3, however, adopts a method in which polyimide resin is coated on a silicon substrate, subsequently a step of forming capacitor circuit and the like is carried out, and finally the silicon substrate is removed by delamination.

For example, with reference to the manufacturing method and the manufacturing flowchart disclosed in the Non-patent Document 2, the concept of a conventional manufacturing method of a thin film decoupling capacitor is described below. As shown in FIG. 9(A), on the surface of a silicon substrate 30, a base polyimide resin 31 is coated to be subjected to curing. Then, on the base polyimide resin 31, a lower electrode forming layer 6, a dielectric layer 7 and an upper electrode forming layer 8 are respectively formed by sputtering deposition to yield a laminated film as shown in FIG. 9(B). The laminated film is machined to a size of a capacitor circuit to result in a state shown in FIG. 9(C). Then, a polyimide resin 31 to be an interlayer insulating film is coated and subjected to curing to yield a state shown in FIG. 10(D). Copper post electrodes 13 are further formed by using a semiadditive method, and a cover film 14 is formed with a photosensitive epoxy resin in a state that predetermined portions remain uncoated to form openings, thus leading to a state shown in FIG. 10(E). Finally, as shown in FIG. 10(F), the silicon substrate is delaminated to yield a desired thin film decoupling capacitor.

When such a capacitor circuit is formed, sputtering deposition is generally adopted for all of the lower electrode forming layer, the dielectric layer and the upper electrode forming layer, to lead to a factor to increase the manufacturing cost. Additionally, the manufacturing unit is limited by the size of silicon wafer, and accordingly a batch manufacturing method is generally adopted, which has been considered problematic from the viewpoints of productivity and manufacturing cost.

Under the above described circumstances, the market has demanded methods capable of manufacturing various capacitor circuits including thin film decoupling capacitors with base made of polyimide resin or the like, excellent in flexibility and electric properties, and also excellent in merit related to manufacturing cost.

In view of the above described circumstances, the present inventors, as a result of a diligent study, have thought out that a film carrier tape with a capacitor circuit is manufactured by applying existing methods for manufacturing a film carrier tape such as the TAB (Tape Automated Bonding) and COF (Chip On Film) methods. Hereinafter, description will be made on the present invention.

<Film Carrier Tape with a Capacitor Circuit According to the Present Invention>

The fundamental structure of a film carrier tape with a capacitor circuit, according to the present invention, is such that the film carrier tape includes a wiring pattern on the surface of a resin film including a plurality of sprocket holes on each of the two edges, wherein the resin film includes solder ball land holes and the wiring pattern includes a capacitor circuit having a structure in which a dielectric layer is disposed between an upper electrode and a lower electrode.

In the film carrier tape with a capacitor circuit, post electrodes, a cover film and solder balls are disposed to form a film carrier tape with a capacitor circuit, capable of permitting surface mounting. Because it is optional whether the post electrodes are disposed or not, the film carrier tape with a capacitor circuit is classified into two types on the basis of the presence/absence of the post electrodes; hereinafter, the two classified types are “a first film carrier tape with a capacitor circuit” provided with no post electrodes and “a second film carrier tape with a capacitor circuit” provided with the post electrodes.

First film carrier tape with a capacitor circuit: The first film carrier tape with a capacitor circuit refers to a type provided with no post electrodes.

More specifically, for the purpose of making the film carrier tape with a capacitor circuit capable of permitting surface mounting, a cover film is preferably provided, in a state without including post electrodes, in such a way that the surface of the upper electrode of the capacitor circuit and the other wiring patterns of the capacitor circuit are partially exposed, and the exposed portions each serve as a solder ball land hole.

The cover film is preferably a cover film formed by using a solder mask.

Also preferably, the bottom of the solder ball land holes in the resin film and the bottom of the solder ball land holes formed in the cover film disposed on the opposite side of the resin film are each provided with an auxiliary metal layer made of any one of a gold-copper alloy layer, a gold-copper-silicon alloy layer, a nickel layer and a gold layer, and these holes are each provided with a solder ball.

Second film carrier tape with a capacitor circuit: The second film carrier tape with a capacitor circuit refers to a type provided with the post electrodes.

Accordingly, the wiring pattern can be provided with the post electrodes to be terminal pads.

A cover film is provided in such a way that the surface of the post electrodes and the surface of the upper electrode of the capacitor circuit are partially exposed, and the exposed portions each serve as a solder ball land hole.

The cover film is preferably a cover film formed by using a solder mask.

Also preferably, the bottom of the solder ball land holes in the resin film and the bottom of the solder ball land holes formed in the cover film disposed on the opposite side of the resin film are each provided with an auxiliary metal layer made of any of a gold-copper alloy layer, a gold-copper-silicon alloy layer, a nickel layer and a gold layer, and these holes are each provided with a solder ball.

<A Method for Manufacturing the Film Carrier Tape with a Capacitor Circuit According to the Present Invention>

The method for manufacturing the film carrier tape with a capacitor circuit according to the present invention can be classified into two types of manufacturing methods on the basis of whether an adhesive layer is present or not between the resin film and a conductor layer on the resin film; thus the two classified manufacturing methods are referred to as a first manufacturing method and a second manufacturing method.

First manufacturing method: The manufacturing method is related to the case where an adhesive layer is present between the resin film and the conductor layer on the resin film. More specifically, it is preferable to adopt a method for manufacturing a film carrier tape with a capacitor circuit, the method comprising the following steps A to D.

Step A: A step of forming an adhesive layer, wherein except for the two widthwise edge areas (the areas in which a plurality of sprocket holes are to be formed) of a resin film wound in a form of reel wound off from the resin film, the adhesive layer and a protective film are continuously bonded onto the central area of the resin film and onto the adhesive layer; and the resin film is wound in a form of reel to form a first film reel;

Step B: A perforation step, wherein the resin film including the adhesive layer and the protective film is wound off from the first film reel; sprocket holes are continuously formed in the two widthwise edge areas of the resin film and solder ball land holes are continuously formed in the central area of the resin film; and the resin film is wound in a form of reel to form a second film reel;

Step C: A lamination step, wherein the perforated resin film is wound off from the second film reel, the protective film is peeled off therefrom; an upper electrode forming layer, a dielectric layer and a lower electrode forming layer are formed on the adhesive layer; and the adhesive layer is cured in a state of a reel to form a third film reel; and

Step D: A step of forming a capacitor circuit, wherein the adhesive layer-cured resin film is wound off from the third film reel; the upper electrode forming layer is patterned to form the shape of an upper electrode circuit; the dielectric layer is exposed in the portion other than the upper electrode circuit; the exposed portion of the dielectric layer is removed; and the thus processed resin film is wound in a form of reel to form a film carrier tape with a capacitor circuit, including solder ball land holes and including, in the wiring pattern, a capacitor circuit (a structure in which a dielectric layer is disposed between the upper electrode and the lower electrode).

The step D in the method for manufacturing a film carrier tape with a capacitor circuit preferably comprises a step of etching the upper electrode again to trim the upper electrode after removing the dielectric layer.

The method for manufacturing a film carrier tape with a capacitor circuit may comprise a step of forming a lower electrode circuit in which the exposed portion of the dielectric layer is removed to partially expose the lower electrode forming layer, and the lower electrode forming layer is patterned to form a desired lower electrode circuit.

The method for manufacturing a film carrier tape with a capacitor circuit may further comprise a step of providing post electrodes to be terminal pads on the wiring pattern.

The method for manufacturing a film carrier tape with a capacitor circuit according to the present invention, it is preferably comprise a step of providing a cover film in such a way that the surface of the upper electrode of the capacitor circuit and the other wiring patterns (the terminal pads are included as the case may be) of the capacitor circuit are partially exposed, and the exposed portions each serve as a solder ball land hole.

The method for manufacturing a film carrier tape with a capacitor circuit according to the present invention may further comprise a step of providing the bottom of the solder ball land holes in the resin film and the bottom of solder ball land holes in the cover film with an auxiliary metal layer made of any of a gold-copper alloy layer, a gold-copper-silicon alloy layer, a nickel layer and a gold layer.

Further, in the method for manufacturing a film carrier tape with a capacitor circuit according to the present invention, addition of a step of disposing a solder ball in each of the solder ball land holes in the resin film and the solder ball land holes in the cover film makes it possible to manufacture a film carrier tape with a capacitor circuit, capable of permitting surface mounting.

Second manufacturing method: The second manufacturing method is related to the case where an adhesive layer is absent between the resin film and the conductor layer on the resin film. More specifically, it is preferable to adopt a method for manufacturing a film carrier tape with a capacitor circuit, the method comprising the following steps A to E.

Step A: A step of forming a lower electrode forming layer, wherein except for the two widthwise edge areas (the areas in which a plurality of sprocket holes are to be formed) of a resin film wound in a form of reel wound off from the resin film, a conductor layer (a lower electrode forming layer) is continuously provided in the central area of the resin film to form a resin film with a conductor layer, which is wound in a form of reel to form a first film reel;

Step B: A step of forming a dielectric layer, wherein the resin film with the lower electrode forming layer formed thereon is wound off from the first film reel; the dielectric layer is formed on the lower electrode forming layer; and further a conductor layer (an upper electrode forming layer) is continuously formed on the dielectric layer to form a second film reel;

Step C: A perforation step, wherein the resin film with the dielectric layer and the upper electrode forming layer formed thereon is wound off from the second film reel; and sprocket holes are continuously formed in the two widthwise edge areas of the resin film; and the resin film is wound in a form of reel to form a third film reel;

Step D: A step of forming solder ball land holes, wherein the resin film with the sprocket holes formed therein is wound off from the third film reel; and predetermined portions of the resin film are removed from the surface of the resin film to continuously form solder ball land holes in the resin film, which is wound to form a fourth film reel; and

Step E: A step of forming a capacitor circuit, wherein the resin film is wound off from the fourth film reel; the upper electrode forming layer is patterned to form the shape of an upper electrode circuit; the dielectric layer is exposed in the portion other than the upper electrode circuit; the exposed portion of the dielectric layer is removed; and the thus processed resin film is wound in a form of reel to form a film carrier tape with a capacitor circuit, including solder ball land holes and including, in the wiring pattern, a capacitor circuit (a structure in which a dielectric layer is disposed between the upper electrode and the lower electrode).

The step E in the method for manufacturing a film carrier tape with a capacitor circuit preferably comprises a step of etching the upper electrode again to trim the upper electrode after removing the dielectric layer.

The method for manufacturing a film carrier tape with a capacitor circuit may further comprise a step of forming a lower electrode circuit in which the exposed portion of the dielectric layer is removed to partially expose the lower electrode forming layer, and the lower electrode forming layer is patterned to form the lower electrode circuit.

The method for manufacturing a film carrier tape with a capacitor circuit may further comprise a step of providing post electrodes to be terminal pads on the wiring pattern.

The method for manufacturing a film carrier tape with a capacitor circuit preferably comprises a step of providing a cover film in such a way that the surface of the upper electrode of the capacitor circuit and the other wiring patterns (the terminal pads are included as the case may be) of the capacitor circuit are partially exposed, and the exposed portions each serve as a solder ball land hole.

The method for manufacturing a film carrier tape with a capacitor circuit preferably comprises a step of providing the bottom of the solder ball land holes in the resin film and the bottom of the solder ball land holes in the cover film with an auxiliary metal layer made of any of a gold-copper alloy layer, a gold-copper-silicon alloy layer, a nickel layer and a gold layer.

Further, in the method for manufacturing a film carrier tape with a capacitor circuit according to the present invention, addition of a step of disposing a solder ball in each of the solder ball land holes in the resin film and the solder ball land holes in the cover film makes it possible to manufacture a film carrier tape with a capacitor circuit, capable of permitting surface mounting.

In the second method for manufacturing a film carrier tape with a capacitor circuit according to the present invention, there is used a resin film with a conductor layer in which no adhesive layer is present between the resin film and the conductor layer on the resin film. Accordingly, for the resin film with a conductor layer formed in the step A, there can be used a resin film with a conductor layer obtained by bonding polyimide resin and copper foil to each other.

For the resin film with a conductor layer to be formed in the step A, there can be used an article obtained by casting polyimide resin onto the surface of a copper foil.

For the resin film with a conductor layer to be used in the step A, there can be used an article obtained by forming a metal layer on polyimide resin by aerosol deposition.

For the resin film with a conductor layer to be formed in the step A, there can be used an article obtained in a manner that a seed layer, made of any of copper, nickel, cobalt or alloys of these metals, is formed on the resin film by sputtering deposition or by direct metallization, and thereafter any of copper, nickel and a nickel alloy is electrodeposited on the seed layer to grow the conductor layer.

For the dielectric layer to be formed in the step D in the second method for manufacturing a film carrier tape with a capacitor circuit according to the present invention, it is preferable to use any of sputtering deposition and aerosol deposition.

Further, for the upper electrode forming layer to be formed in the step D, it is preferable to use any of sputtering deposition and aerosol deposition.

<Surface-Mounted Film Carrier Tape with a Capacitor Circuit According to the Present Invention>

Surface-mounting of electronic components such as flip chips on the sites provided with solder balls in the above described film carrier tape with a capacitor circuit leads to formation of a lengthy surface-mounted film carrier tape with a capacitor circuit.

Alternatively, a lengthy surface-mounted film carrier tape with a capacitor circuit can be obtained by adopting a method in which the film carrier tape with a capacitor circuit in a form of reel is wound off and electronic components are mounted by bonding at predetermined positions by means of a bonder device, as a method for surface-mounting of electronic components on the above described film carrier tape with a capacitor circuit.

The film carrier tape with a capacitor circuit according to the present invention is an article in which circuit forms such as a capacitor circuit and a terminal pad are optionally formed on a resin film made of polyimide, PET or the like. Accordingly, there can be easily made a thin film decoupling capacitor, excellent in flexibility, made of a resin such as polyimide resin. The film carrier tape with a capacitor circuit has a tape-shaped form, and can make a reel when winding, which facilitates the handling thereof at the time of delivery or the like. The shipping state of the film carrier tape with a capacitor circuit can take various states such as a state in which a capacitor circuit is formed on the surface of a resin film, a state in which a capacitor circuit and post electrodes are formed on the surface of a resin film, a state in which a capacitor circuit, post electrodes and a cover film are formed on the surface of a resin film, and a state in which a capacitor circuit, post electrodes and a cover film are formed and solder balls are disposed on the surface of a resin film. Further, there is formed a surface-mounted film carrier tape with a capacitor circuit in which mounting of components has been carried out from a state in which a capacitor circuit, a cover film and the like are formed and solder balls are disposed on the surface of a resin film; and such a film carrier tape manufactured from this state in a form of reel can be shipped.

Additionally, the manufacture of the film carrier tape with a capacitor circuit according to the present invention can adopt steps similar to those for conventional TAB products, and does not need the use of silicon substrates or the like. Specifically, while the tape carrier is traveling in the various steps, formation of various coating films, etching and the like can also be continuously carried out; thus the manufacture of the film carrier tape concerned permits manufacturing a film carrier tape with a capacitor circuit excellent in industrial productivity, low in price, excellent in quality stability and having flexibility.

### BRIEF DESCRIPTION OF THE DRAWINGS

FIG. 1 shows schematic sectional views illustrating a manufacturing process of a film carrier tape with a capacitor circuit according to the present invention (for a case where an adhesive layer is included);

FIG. 2 shows schematic sectional views illustrating the manufacturing process of the film carrier tape with a capacitor circuit according to the present invention;

FIG. 3 shows schematic sectional views illustrating the manufacturing process of the film carrier tape with a capacitor circuit according to the present invention;

FIG. 4 shows schematic sectional views illustrating the manufacturing process of the film carrier tape with a capacitor circuit according to the present invention;

FIG. 5 shows schematic sectional views illustrating a manufacturing process of a film carrier tape with a capacitor circuit (a lower electrode forming layer/a dielectric layer/an upper electrode forming layer) according to the present invention;

FIG. 6 shows schematic sectional views illustrating a manufacturing process of a film carrier tape with a capacitor circuit according to the present invention (for a case where no adhesive layer is included);

FIG. 7 shows schematic sectional views illustrating the manufacturing process of the film carrier tape with a capacitor circuit according to the present invention (for the case where no adhesive layer is included);

FIG. 8 shows schematic sectional views illustrating the manufacturing process of the film carrier tape with a capacitor circuit according to the present invention (for the case where no adhesive layer is included);

FIG. 9 shows schematic sectional views illustrating the flow of a process for forming a capacitor circuit on a polyimide resin according to a conventional manufacturing method; and

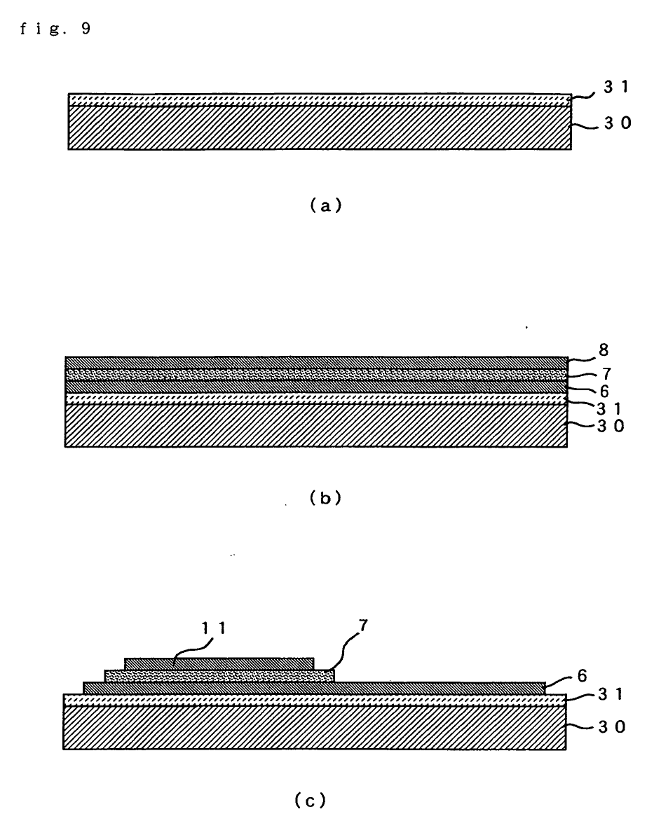

FIG. 10 shows schematic sectional views illustrating the flow of the process for forming the capacitor circuit on the polyimide resin according to the conventional manufacturing method.

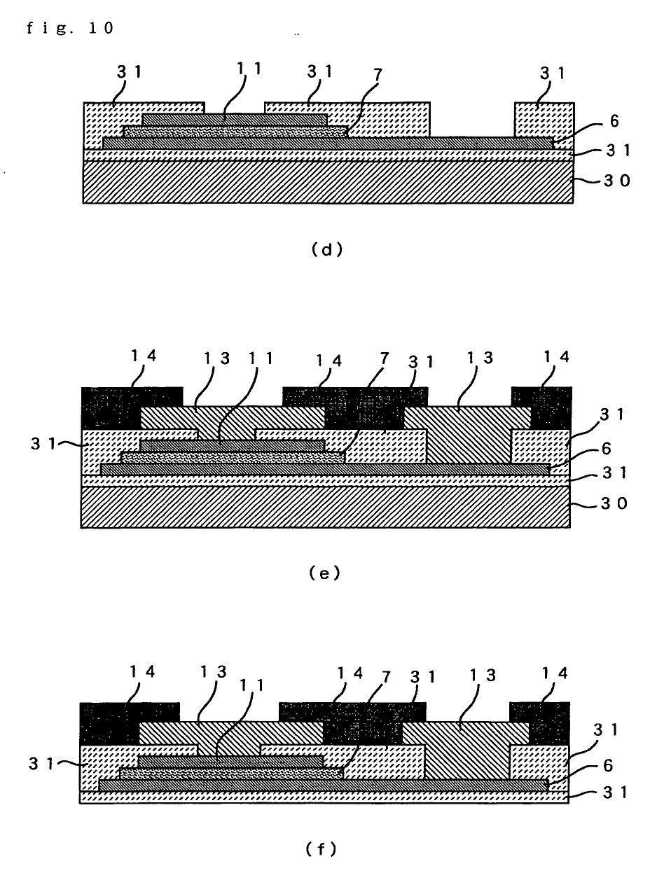

### DETAILED DESCRIPTION OF THE PREFERRED EMBODIMENTS

Hereinafter, description will be made on the mode of the film carrier tape with a capacitor circuit according to the present invention, the manufacturing mode of the film carrier tape with a capacitor circuit according to the present invention, and the mode of the surface-mounted film carrier tape with a capacitor circuit according to the present invention.

<Mode of the Film Carrier Tape with a Capacitor Circuit According to the Present Invention>

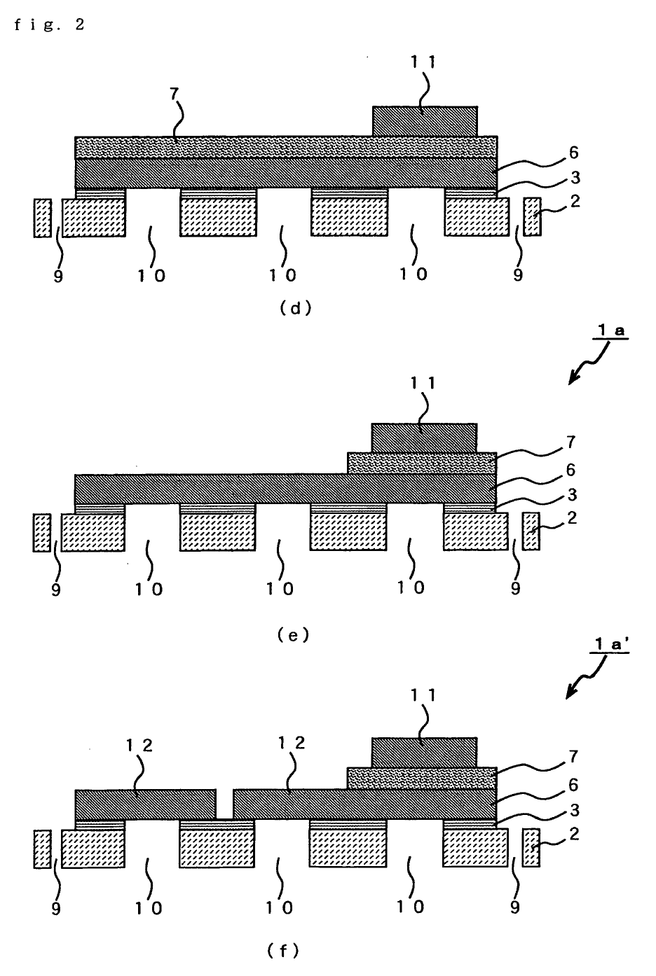

As shown in FIG. 2(E), the fundamental structure of a film carrier tape 1a with a capacitor circuit, according to the present invention, is such that the film carrier tape includes a wiring pattern on the surface of a resin film 2 including a plurality of sprocket holes 9 on each of the two edges thereof, wherein the resin film 2 includes solder ball land holes 10 and the wiring pattern includes a capacitor circuit having a structure in which a dielectric layer 7 is disposed between an upper electrode 11 and a lower electrode forming layer 6. Here, it should be clearly noted that, in order to facilitate illustration, the figure adopts the thickness of each of the layers that does not reflect the actual thickness proportion in an actual product and the figure presents a schematic sectional view adopting the simplest configuration and an easy-to-understand depiction scheme; this is also the case for all the other figures.

Description will be made on the reasons for the adoption of such a structure in which on both sides thereof, terminals capable of permitting mounting of components or capable of being connected to another substrate are disposed. Specifically, from the theoretical point of view, reduction of the distance between each of the chip components and the capacitor makes it possible to reduce the loop inductances. It can be the that, for that purpose, as compared to surface mounting or embedding in the circuit substrate of the capacitor, better is a mounting scheme to make as shortest as possible the distance between a chip component and the circuit substrate (motherboard) by disposing the capacitor between the chip component and the circuit substrate. In other words, when there are bumps (solder balls in the present specification) to be connection terminals on both sides as in the film carrier tape with a capacitor circuit according to the present invention, electronic components can be connected on one side and substrate terminals can be connected on the other side, thus permitting a straight arrangement along the vertical direction, so that the distance between each of the electronic components and the circuit can be made shortest. On the contrary, in the cases of capacitor circuits in which connectable terminals are disposed only on one side as disclosed in above described Non-patent Documents 1 to 3, connection to another substrate is inevitably made along the horizontal direction, leading to a result that the distance between each of the mounted electronic components and the substrate circuit becomes long, which adversely affects the decrease of the loop inductance.

In the film carrier tape with a capacitor circuit according to the present invention, it is possible to prepare an optional number of regions to be pads permitting mounting of electronic components. For example, when there is to be mounted a so-called 256-pin flip chip in which there are 256 bump regions, the electrode pitch is 120 μm, and the electrode size is 65 μm×65 μm, it is necessary that a circuit provided with terminals to be pad regions to meet this pin number should be included in the film carrier tape with a capacitor circuit. In this way, even when the pad portions for the electronic components increase or decrease, the film carrier tape with a capacitor circuit according to the present invention can cope with such a case in an adapted manner.

Here, for the resin film 2, there can be used films such as polyimide resin film, PET film and aramid film. No particular constraint is imposed on the thickness of each of these resin films. The sprocket holes serve as the positions engaging with the driving gears to continuously travel the resin film in predetermined steps, and also work as markers for positioning the processing positions. Further, the solder ball land holes 10 as referred to herein are obtained by perforation processing of the resin film.

A conductor layer (a lower electrode forming layer 6) to form the lower electrode 12 is disposed on the surface of the resin film 2, and there may be disposed or may not be disposed an adhesive layer 3 between the resin film 2 and the conductor layer (the lower electrode forming layer 6). However, the manufacturing method to be described later is largely affected by whether the adhesive layer 3 is present or not.

The other constituent components will be described below. Hereinafter, for the convenience of description, the film carrier tape with a capacitor circuit is classified into “the first film carrier tape with a capacitor circuit” and “the second film carrier tape with a capacitor circuit.”

First film carrier tape with a capacitor circuit: The first film carrier tape with a capacitor circuit refers to a type provided with no post electrodes; for the purpose of making the film carrier tape with a capacitor circuit capable of permitting surface mounting, the degree of processing is raised in the following order.

Specifically, from the film carrier tape 1a (fundamental structure) with a capacitor circuit, shown in FIG. 2(E), by forming the lower electrode circuit 12 by etching the lower electrode forming layer 6 or by other operations, there is obtained a film carrier tape 1a′ with a capacitor circuit, provided with the lower electrode circuit 12, as shown in FIG. 2(F).

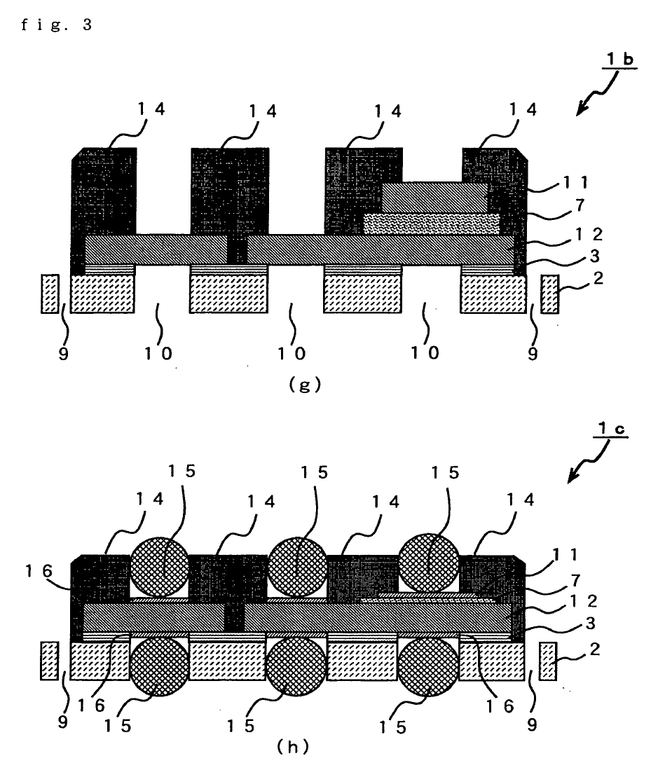

From the film carrier tape 1a or 1a′ with a capacitor circuit, as the fundamental structure, by providing a cover film 14 in such a way that the surface of the upper electrode of the capacitor circuit and the other wiring patterns of the capacitor circuit are partially exposed, there is obtained a film carrier tape 1b with a capacitor circuit in which the exposed portions each serve as a solder ball land hole, as shown in FIG. 3(G). Accordingly, the thickness of the cover film 14 is preferably such that it permits forming recesses to serve as solder ball land holes 10, and is not particularly limited as long as the cover film 14 serves as a protective film to ensure the reliability of the dielectric layer. Accordingly, the width or the like of each of the solder ball land holes 10 is optionally determined in view of the sizes of the solder balls needed to be provided therein in consideration of the pitch and the like of the pad of the electronic components to be finally surface mounted.

In forming the cover film 14, a thermosetting epoxy resin, a photosensitive epoxy resin and the like can be used. The cover film 14 is also preferably formed with such a solder mask as widely used in manufacturing of printed wiring boards. The solder mask as referred to herein means a solder mask formed with a solder resist ink, and is preferable as a protective film to maintain over a long period the reliability of the dielectric layer. Further, the cover film 14 can be provided as a structure of two layers composed of a highly insulating resin such as polyimide resin and the epoxy resin or the solder mask.

As shown in FIG. 3(H), preferably, the bottom of the solder ball land holes in the resin film and the bottom of solder ball land holes formed in the cover film disposed on the opposite side of the resin film are each provided with an auxiliary metal layer 16 made of any of a gold-copper alloy layer, a gold-copper-silicon alloy layer, a nickel layer and a gold layer, and these holes are each provided with a solder ball. The auxiliary metal layer 16 serves to increase the bonding strength at the time of the bonding carried out with the solder balls melted by a predetermined heat. When the solder balls are disposed on the auxiliary metal layers, the solder balls are held without fail by disposing the solder balls through the intermediary of a conductive adhesive. A state of the solder balls having been disposed in such a way leads to a film carrier tape 1c with a capacitor circuit, capable of permitting surface mounting. Here, it should be clearly noted that the solder balls as referred to in the present invention are not constrained to spherical shapes, but can be used in the forms of tablets, spindles and the like.

Second film carrier tape with a capacitor circuit: The second film carrier tape with a capacitor circuit refers to a type provided with post electrodes; for the purpose of making the film carrier tape with a capacitor circuit capable of permitting surface mounting, the degree of processing is raised in the following order.

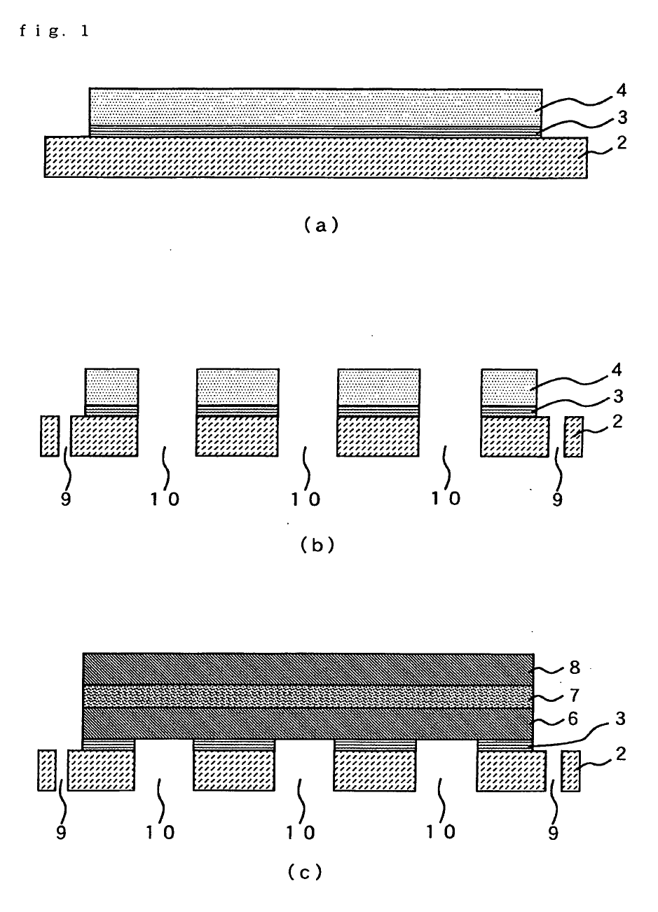

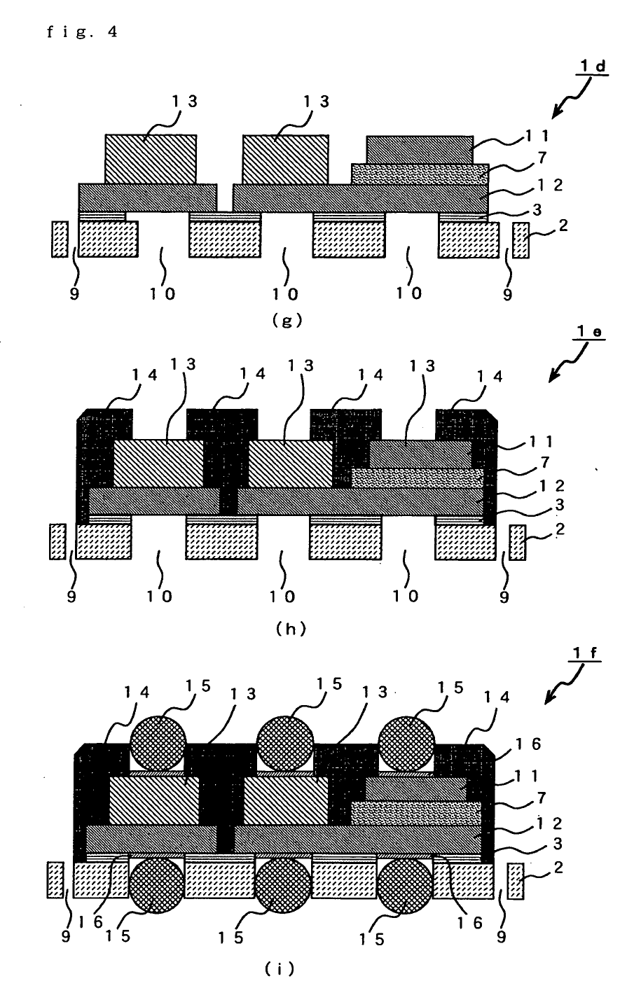

From the film carrier tape 1a (or 1a′) with a capacitor circuit, as the fundamental structure obtained by the steps shown in FIG. 1(A) to FIG. 2(E) (or FIG. 2(F)), there is obtained a film carrier tape with a capacitor circuit, provided with the post electrodes 13 to serve as terminal pads on the wiring pattern, as shown in FIG. 4(G). Specifically, it is easy to adopt, as a film carrier tape 1d with a capacitor circuit according to the present invention, a mode in which terminal pads and capacitor circuits are alternately disposed, and such a structure is a structure to be preferably applied to a thin layer decoupling capacitor element.

In the case where the post electrodes are provided, the cover film 14 is provided in such a way that the surface of the post electrodes 13 and the surface of the upper electrode 11 of the capacitor circuit are partially exposed, as shown in FIG. 4(H), and the exposed portions are each made to serve as a solder ball land hole 10; for that purpose, it is preferable to obtain a state of a film carrier tape 1e with a capacitor circuit. As for the cover film 14 as referred to herein, the above described concept applied to the cover film can be applied as it is. In other words, a thermosetting epoxy resin, a photosensitive epoxy resin and the like can be used. The cover film 14 is also preferably formed with such a solder mask as widely used in manufacturing of printed wiring boards. Further, the cover film 14 can be provided as a structure of two layers composed of a highly insulating resin such as polyimide resin and the epoxy resin or the solder mask.

As shown in FIG. 4(I), preferably, the bottom of the solder ball land holes in the resin film and the bottom of solder ball land holes formed in the cover film disposed on the opposite side of the resin film are each provided with an auxiliary metal layer 16 made of any of a gold-copper alloy layer, a gold-copper-silicon alloy layer, a nickel layer and a gold layer, and these holes are each provided with a solder ball. The auxiliary metal layer 16 serves to increase the bonding strength at the time of the bonding carried out with the solder balls melted by a predetermined heat. When the solder balls are disposed on the auxiliary metal layers, the solder balls are held without fail by disposing the solder balls through the intermediary of a conductive adhesive. A state of the solder balls having been disposed in such a way leads to a film carrier tape 1f with a capacitor circuit, capable of permitting surface mounting.

<Method for Manufacturing a Film Carrier Tape with a Capacitor Circuit According to the Present Invention>

As described above, the method for manufacturing the film carrier tape with a capacitor circuit according to the present invention can be classified into two types of manufacturing methods on the basis of whether an adhesive layer is present or not between the resin film and the conductor layer on the resin film. Hereinafter, the embodiment of the first manufacturing method and the embodiment of the second manufacturing method will be described one after another.

Embodiment of the first manufacturing method: The manufacturing method refers to a case where an adhesive layer is present between the resin film and the conductor layer on the resin film. In other words, it is preferable to adopt a method for manufacturing a film carrier tape with a capacitor circuit wherein the manufacturing method passes through the following steps A to D. For a film carrier tape, the following sequence of procedures is adopted: a resin film in a form of tape is wound off from a state wound by a winding reel (hereinafter, simply referred to as “a form of reel”); the tape itself is made to travel through the steps; while being traveling, the tape undergoes various treatments such as etching, patterning and plating in such a way that the tape is once wound at a proper stage of a step to be conveyed to the next step.

Step A: This step is a step of forming the adhesive layer wherein as shown in FIG. 1(A), on the resin film 2, the adhesive layer 3 and the protective film 4 are disposed. Specifically, except for the two widthwise edge areas (the areas in which a plurality of holes are to be formed) of a resin film wound in a form of reel wound off from the resin film, the adhesive layer and a protective film are continuously bonded onto the central area of the resin film and onto the adhesive layer; and the resin film is wound in a form of reel to form a first film reel. Here, the two widthwise edge areas of a resin film mean the areas in which a plurality of sprocket holes are to be formed.

When the adhesive layer is disposed in the central area of the resin film and the protective film 4 is disposed on the adhesive layer 3 by continuous bonding, any of the following two methods may be adopted: one is a method in which the adhesive layer is beforehand formed by coating and drying in the central area of the resin film, and then the protective film is continuously bonded onto the adhesive layer; and the other is a method in which a protective film provided with an adhesive layer is continuously bonded onto the central area of the resin film. As the adhesive to be used herein, an epoxy adhesive used in TAB manufacturing is preferably used. As for the protective film, the material quality thereof is not particularly limited, but films made of PET and the like are generally used.

Step B: This step is a perforation step wherein, as shown in FIG. 1(B), perforation processing to form the sprocket holes 9 and the solder ball land holes 10 is carried out. The resin film including the adhesive layer and the protective film is wound off from the first film reel; sprocket holes are continuously formed in the two widthwise edge areas of the resin film and the solder ball land holes are continuously formed in the central area of the resin film; and the resin film is wound in a form of reel to form a second film reel. In the formation of the sprocket holes and the solder ball land holes, processing based on blanking with dies is preferably applied. The use of dies permits maintaining high precision for the sprocket holes and the solder ball land holes.

Step C: This step is a lamination step wherein, as shown in FIG. 1(C), a lower electrode forming layer 6, a dielectric layer 7 and an upper electrode forming layer 8 are formed on the adhesive layer 3. The perforated resin film 2 is wound off from the second film reel, the protective film 4 is peeled off therefrom; the lower electrode forming layer, the dielectric layer and the upper electrode forming layer are formed on the adhesive layer; and the adhesive layer is cured in a state of reel to form a third film reel.

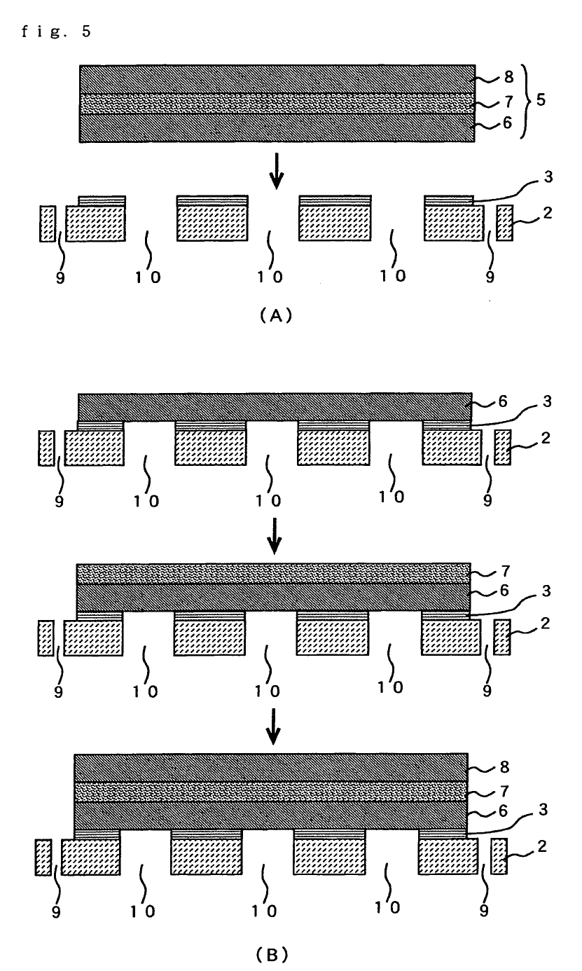

For the purpose of forming the lower electrode forming layer, the dielectric layer and the upper electrode forming layer on the adhesive layer, two methods can be adopted, as is described with reference to FIG. 5. One is a method in which, as shown in FIG. 5(A), a capacitor layer forming material 5 already having a laminate structure of the lower electrode forming layer 6/the dielectric layer 7/the upper electrode forming layer 8 disposed in this order is bonded onto the adhesive layer 3. No particular constraint is imposed on the method for manufacturing the capacitor layer forming material 5. For example, on the surface of a metal foil to be the lower electrode forming layer, the dielectric layer may be formed by means of various methods such as a coating method, a sol-gel method, sputtering deposition, a CVD method and aerosol deposition; and the upper electrode may be formed on the dielectric layer by means of electrochemical methods such as plating (inclusive of electroless plating), sputtering deposition, aerosol deposition and the like. Here, the thickness of each of the lower electrode forming layer 6, the dielectric layer 7, and the upper electrode forming layer 8 is varied according to the product specifications, and thus, does not need any particular constraint to be imposed thereon.

The other is a method in which, according to the procedures shown in FIG. 5(B), a metal foil to be the lower electrode forming layer 6 is bonded to the adhesive layer 3, and the dielectric layer 7 is formed on the metal foil by means of a method capable of forming the dielectric layer at low temperatures such as a coating method of coating a dielectric powder-containing resin, sputtering deposition and aerosol deposition; further, the upper electrode forming layer 8 is formed on the dielectric layer 7 by means of electrochemical methods such as plating (inclusive of electroless plating) sputtering deposition, aerosol deposition, and the like.

Aerosol deposition as referred to herein means a method for forming a dielectric layer in which method the material that can be used as a dielectric material is an inorganic oxide such as PZT and BiZrO₃, fine particles of 0.02 μm to 2.0 μm in particle size are mixed with a gas to prepare an aerosol, and the aerosol is passed through a nozzle (with an aperture diameter of 1 mm or less) in an atmosphere under a reduced pressure of 50 to 1000 Pa to form a flow of the particles accelerated to a few 100 m/sec, which flow is made to collide with the positions corresponding to the coating film formation to form the dielectric layer. This method characteristically provides a satisfactory film density and a satisfactory film adhesion, and further, an excellent insulation exhibited by the formed dielectric layer. For the purpose of avoiding a duplicate description on aerosol deposition, here are also described the lower electrode forming layer and the upper electrode forming layer that are formed by aerosol deposition; more specifically, the raw materials to be used in aerosol deposition are a powder of copper, a powder of nickel, a powder of a nickel alloy, a powder of gold and the like, and each of these raw materials are used as a predetermined metal material in a form of fine particles of 0.02 μm to 2.0 μm in particle size, and thus, the lower electrode forming layer and the upper electrode forming layer can be formed.

No particular constraint is imposed on the curing, and the curing conditions appropriate to the properties of the adhesive can be adopted. For example, the curing conditions are generally such that, in order to prevent the occurrence of bubbling, there is adopted a step curing in which the curing temperature is stepwise increased up to a temperature of the order of 160° C. This concept of curing holds for all the curing treatments in the present invention.

Step D: This step is a step of forming a capacitor circuit, wherein the capacitor circuit is formed. Specifically, the adhesive layer-cured resin film is wound off from the third film reel; the upper electrode forming layer is patterned to form the shape of the upper electrode circuit; and the dielectric layer is exposed in the portion other than the upper electrode circuit. For the purpose of forming the upper electrode circuit from the upper electrode forming layer, patterning based on the hitherto well known etching method, photolithographic method, sputtering method and the like can be carried out. Thus, after the upper electrode circuit 11 has been formed, the dielectric layer 7 is partially exposed as can be seen from FIG. 2(D).

Then, the exposed portion of the dielectric layer 7 is removed. For the removal of the dielectric layer 7, a buffing method, a solution treatment using a desmear solution, an abrasive removal with blast particles based on a blast method (particularly preferably the wet blast method being used), and a sputtering method using argon ions can be used. When the blast method is used, if an etching resist layer is present on the surface of the upper electrode circuit, the etching resist layer can be used as a protective layer without peeling off thereof, for the purpose of restricting the damage of the upper electrode circuit due to blast particles to the lowest limit. When the sputtering method is used, the surface of the upper electrode circuit is preferably provided with a protective mask by masking, and then the sputtering processing is carried out. When the removal of the unnecessary portions of the dielectric layer has been thus completed, the film carrier tape is wound in a form of reel, to yield a film carrier tape with a capacitor circuit, including the solder ball land holes and including, in the wiring pattern, the capacitor circuit (the structure in which the dielectric layer is disposed between the upper electrode and the lower electrode) FIG. 2(E) shows a schematic sectional view of this film carrier tape with a capacitor circuit.

On completion of such removal of the dielectric layer as described above, the dielectric layer portion in the vicinity of the end of the upper electrode tends to be damaged, and the end of the upper electrode circuit and the end of the lower electrode circuit tend to be short-circuited. Accordingly, it is preferable to adopt a step of trimming the upper electrode in which step a small area of the periphery of the upper electrode circuit is removed by etching, although the area of the upper electrode is made smaller, and the portion to be short-circuited is thereby removed. For the etching in this step, a dry etching such as sputtering can be used, but preferable is a processing in which a photosensitive etching resist layer is formed and an etching solution is used. This step of trimming the upper electrode can be carried out simultaneously with the etching of the lower electrode to be described below.

Further, when the manufacturing of the film carrier tape with a capacitor circuit is carried out by means of the above described manufacturing method, there is obtained a state in which a part of the lower electrode forming layer is exposed. Thus, if needed, there can be added a step of forming the lower electrode circuit in which step the desired lower electrode circuit is formed by patterning the lower electrode forming layer. For the formation of the lower electrode circuit in this step, patterning can be carried out by using the same, hitherto well known etching method, photolithographic method, sputtering method and the like as in the formation of the upper electrode circuit. Thus, after the lower electrode circuit 12 has been formed, there is obtained a state as shown in FIG. 2(F).

By addition of a step of providing the post electrodes 13 to be the terminal pads on the wiring pattern, in the above described method for manufacturing the film carrier tape with a capacitor circuit, there can be obtained a state as shown in FIG. 3(G). This formation of the post electrodes 13 can be carried out by forming the post electrodes 13 on the surface of the lower electrode 12 by using the hitherto well known methods such as an electrolysis method and sputtering deposition. For the material of the post electrodes 13, various materials such as copper, aluminum, nickel and a nickel alloy can be used.

The method for manufacturing the film carrier tape with a capacitor circuit according to the present invention preferably comprises a step of providing the cover film 14 in such a way that the surface of the upper electrode 11 of the capacitor circuit and the other wiring patterns (which may include terminal pads as the case may be) of the capacitor circuit are partially exposed and the exposed portions each serve as a solder ball land hole, and thus there is obtained a state as shown in FIG. 3(G) or FIG. 4(H).

For the formation of the cover film 14 in this step, there can be used a thermosetting epoxy resin, a photo sensitive epoxy resin or the like. When the former thermosetting epoxy resin is used, the resin concerned is coated by a screen printing method to be cured, and the cured epoxy resin in the predetermined areas is removed, with the aid of the mask method, by argon sputtering or the like. When the latter photosensitive epoxy resin is used, the light exposure is made in such a way that the epoxy resin in the predetermined positions can be removed afterward, and thus, only the epoxy resin in the positions needing it is made to remain. Specifically, it is also preferable to use, in the formation of the cover film, the solder mask widely used in manufacturing printed wiring boards. This is because the solder mask is a type of epoxy resin, is excellent in long term reliability of electric insulation in the same manner as epoxy resin, and is easy to coat on fine areas by use of a screen printing method; and in addition, the solder mask efficiently prevents adhesion of solder to the positions needing no solder, in accordance with the primary way of using it. When the solder mask is used, it is also possible that, in the same manner as when a thermosetting epoxy resin is used, the solder mask is coated on the whole surface to be cured, and the cured epoxy resin in the predetermined areas is removed with the aid of the mask method by argon sputtering or the like.

When the cover film is formed as a two-layer structure, for example, composed of a polyimide resin layer and an epoxy resin layer (or a solder mask), preferably a polyimide resin is coated to be cured, then an epoxy resin layer (or a solder mask) is coated to be cured, and thereafter, the polyimide resin layer and the epoxy resin layer (or the solder mask) in the positions needing no these resin layers are removed by sputtering.

On completion of the formation of the cover film 14 as described above, from the bottom of the solder ball land holes 10 in the resin film and the bottom of the solder ball land holes 10 in the cover film, any of the surface of the upper electrode 11, the surface of the lower electrode 12 and the surface of the post electrodes 13 is exposed. Accordingly, the method preferably comprises a step of providing an auxiliary metal layer 16 made of any of a gold-copper alloy layer, a gold-copper-silicon alloy layer, a nickel layer and a gold layer, unless the materials for the surface of the upper electrode layer, the surface of the lower electrode and the surface of the post electrodes are each any of a gold-copper alloy layer, a gold-copper-silicon alloy layer, a nickel layer and a gold layer. Among the accompanying drawings, the auxiliary metal layer 16 is depicted in FIG. 3(H) or FIG. 4(I).

The method for manufacturing the film carrier tape with a capacitor circuit according to the present invention may further comprise a step of disposing a solder ball 15 in each of the solder ball land holes 10 in the resin film and the solder ball land holes 10 in the cover film. When the solder balls 15 are disposed in the solder ball land holes 10, the solder balls 15 can be held without fail by disposing the solder balls through the intermediary of a conductive adhesive. No particular constraint is imposed on the method for disposing the conductive adhesive. In a state that the solder balls 15 are disposed in such a way, there is obtained a film carrier tape, 1c or 1f, with a capacitor circuit capable of permitting surface mounting, as shown in FIG. 3(H) or FIG. 4(I).

Second manufacturing method: The second manufacturing method is related to the case where no such an adhesive layer as described above is present between the resin film and the conductor layer on the resin film. More specifically, it is preferable to adopt a method for manufacturing a film carrier tape with a capacitor circuit, the method comprising the following steps A to E.

Step A: This step of forming a lower electrode forming layer is a step wherein except for the two widthwise edge areas (the areas in which a plurality of sprocket holes are to be formed) of a resin film wound in a form of reel wound off from the resin film, a conductor layer is provided in the central area of the resin film to form a resin film with a lower electrode forming layer, which is wound in a form of reel to form a first film reel.

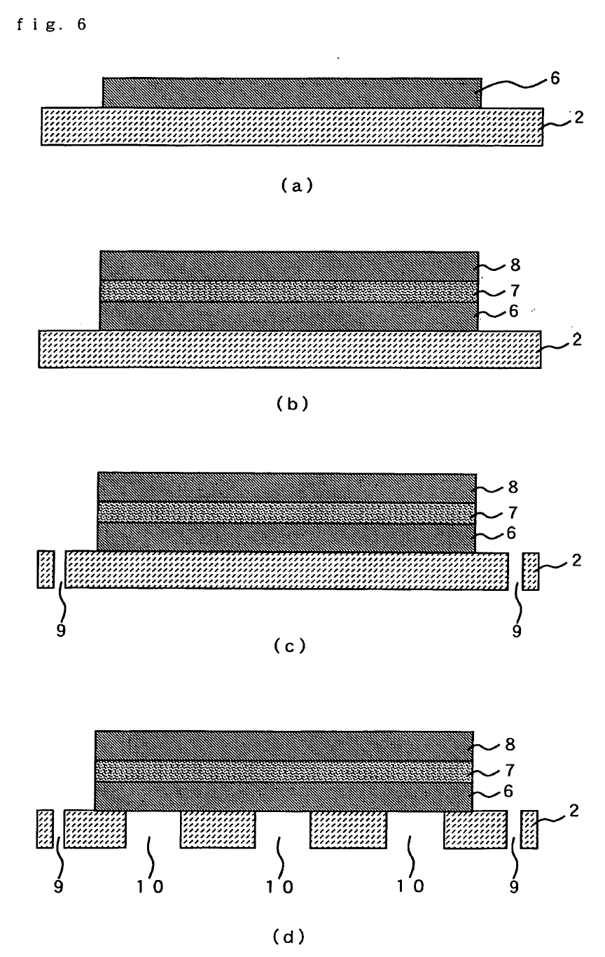

FIG. 6(A) shows a schematic sectional view of a resin film 20 with a lower electrode forming layer in which a conductor layer (a lower electrode forming layer 6) is provided in the central area of a resin film. The resin film with a lower electrode forming layer is preferably formed by means of any one of the following manufacturing methods.

For the resin film with a lower electrode forming layer, there is used a resin film with a lower electrode forming layer in which film no adhesive layer is present between the resin film and the conductor layer on the resin film. Accordingly, for the resin film with a lower electrode forming layer to be used in the step A, there can be used an article obtained by bonding a polyimide resin and a copper foil to each other. Alternatively, for the resin film with a lower electrode forming layer to be used in the step A, there can be used an article obtained by casting a polyimide resin onto the surface of a copper foil. Yet alternatively, a metal layer can be formed on the surface of a polyimide resin by aerosol deposition. These techniques are well known in the art to be generally, widely used, and hence, detailed description of the manufacturing methods will be omitted.

For the resin film with a conductor layer to be formed in the step A, it is preferable to use an article obtained in such a manner that a seed layer, made of any of copper, nickel, cobalt and alloys of these metals, is formed on the resin film by sputtering deposition or by direct metallization, and thereafter any of copper, nickel and a nickel alloy is electrodeposited on the seed layer to grow the conductor layer. This is because such an article is excellent in adhesion with a film of a resin such as polyimide resin, and the film thickness of such an article can be easily controlled.

When a seed layer made of any of copper, nickel, cobalt and alloys of these metals is provided on a resin film by sputtering deposition, the surface of the resin film is subjected to an adhesion improvement processing such as plasma processing or the like, then the areas needing no deposition are covered by a masking method, and then a sputtering target made of any of copper, nickel, cobalt and alloys of these metals is irradiated with argon ions or the like to deposit the ejected particles only on the central area of the resin film to form the above described seed layer of 0.1 μm to 1 μm in thickness.

On the other hand, when direct metallization is applied, a polyimide resin film is used as the resin film, and the area for forming the seed layer is subjected to alkali treatment with a potassium hydroxide solution or a sodium hydroxide solution so as for the polyimide rings to undergo ring opening treatment to form carboxyl groups on the surface of the resin film. This alkali treatment is carried out by a technique such as soaking the polyimide resin film in an alkali solution, spraying an alkali solution onto the surface of the polyimide resin film, or the like. By covering the surface needing no ring opening treatment with a water-resistant film, even when the polyimide resin film is exposed to the solution in direct metallization to be described below, water absorption and moisture absorption from the covered surface are prevented, to stabilize the resin film so as to provide a high peeling strength after heating.

The polyimide resin film subjected to the ring opening treatment is washed with water to be transferred to a step of neutralization, which step neutralize with an acid solution the surface of the polyimide resin film having carboxyl groups formed by ring opening and being strongly alkalized. For the solution to be used for neutralization, hydrochloric acid is preferably used. Then, the neutralized carboxyl groups are made to contact with a metal ion-containing solution so as for the metal component to be adsorbed on the surface of the polyimide resin film to form a metal carboxylate on the same surface. After washing with water, the metal carboxylate formed on the surface of the polyimide resin film is reduced with sodium borohydride, hypophosphorous acid, dimethylamine and the like, as reducing agents, to form a metal film on the surface of the polyimide resin film. By repeating two or more times this cycle of the adsorption step and the reduction step, there are formed, at the same time, a 10 nm to 80 nm thick amorphous metal film and a mixed layer, of 50 nm to 180 nm in mean thickness, including the metal particles and the polyimide resin mixed with each other.

Then, on these two layers, a thin film made of any of copper, nickel, cobalt and alloys of these metals, of 50 nm to 700 nm in mean thickness, is formed to complete the seed layer. For the formation of this thin film, it is preferable to adopt an electrolytic method using the following plating solution.

When a copper film is formed, there are used solutions usable as the supply source of the copper ion such as a copper sulfate solution and a copper pyrophosphate solution, with no particular constraint imposed on these solutions. For example, when a copper sulfate solution is used, the concentration of cooper is set at 30 g/l to 100 g/l and the concentration of sulfuric acid is set at 50 g/l to 200 g/l; and the conditions are such that the solution temperature is set at 30° C. to 80° C., and the current density is set at 1 A/dm² to 100 A/dm². When a copper pyrophosphate solution is used, the concentration of copper is set at 10 g/l to 50 g/l and the concentration of potassium pyrophosphate is set at 100 g/l to 700 g/l; and the conditions are such that the solution temperature is set at 30° C. to 60° C., the pH is set at 8 to 12, and the current density is set at 1 A/dm² to 10 A/dm².

When a pure nickel thin film is formed, a wide range of solutions used as nickel plating solutions can be used. Examples of such solutions and the related conditions include the following three cases: i) Watt bath and the conditions: nickel sulfate: 240 g/l, nickel chloride: 45 g/l, boric acid: 30 g/l, the solution temperature: 55° C., pH: 5, the current density: 0.2 A/dm²; ii) a sulfamate bath and the conditions: nickel sulfamate: 400 g/l, boric acid: 30 g/l, the solution temperature: 55° C., pH: 4.5, the current density: 0.2 A/dm²; iii) a bath using nickel sulfate and the conditions: nickel: 5 g/l to 30 g/l, potassium pyrophosphate: 50 g/l to 500 g/l, the solution temperature: 20° C. to 50° C., pH: 8 toll, the current density: 0.2 A/dm² to 10 A/dm². Here, it should be clearly noted that the pure nickel thin film as referred to herein means that no alloying elements are intentionally added, but does not mean that inevitable impurities are removed to attain the 100% purity.

When a zinc-nickel alloy thin film is formed, for example, the following solution, conditions and the like are adopted: nickel sulfate is used and the concentration of nickel is 1 g/l to 2.5 g/l; zinc pyrophosphate is used and the concentration of zinc is 0.1 g/l to 1 g/l, the concentration of potassium pyrophosphate is 50 g/l to 500 g/l, the solution temperature is set at 20° C. to 50° C., the pH is set at 8 to 11, and the current density is set at 0.2 A/dm² to 10 A/dm².

When a nickel-cobalt alloy thin film is formed, for example, the following solution, conditions and the like are adopted: cobalt sulfate: 80 g/l to 180 g/l, nickel sulfate: 80 g/l to 120 g/l, boric acid: 20 g/l to 40 g/l, potassium chloride: 10 g/l to 15 g/l, sodium dihydrogen phosphate: 0.1 g/l to 15 g/l, the solution temperature: 30° C. to 50° C., pH: 3.5 to 4.5, the current density: 0.2 A/dm² to 10 A/dm².

By using a phosphoric acid solution, a nickel-phosphorus alloy plating can be carried out. In this case, the following solution, conditions and the like are adopted: nickel sulfate: 120 g/l to 180 g/l, nickel chloride: 35 g/l to 55 g/l, H₃PO₄: 30 g/l to 50 g/l, H₃PO₃: 20 g/l to 40 g/l, the solution temperature: 70° C. to 95° C., pH: 0.5 to 1.5, the current density: 0.2 A/dm² to 10 A/dm².

Then, there is formed the copper layer for use in forming circuits by using an electrochemical technique on the surface of the seed layer which has been formed by sputtering deposition or by direct metallization as described above. Here, the phrase “by using an electrochemical technique” means that the electrochemical technique may include the electroless copper plating that takes advantage of the difference in ionization tendency, the electrolytic copper plating, and a combination of the electroless copper plating and the electrolytic copper plating, and means that as a result of application of the technique, copper is deposited to grow the copper layer, namely, to increase the thickness of the copper layer to lead to a state of the layer that can work as the lower electrode forming layer. Here, the compositions of the electroless copper plating bath and the electrolytic copper plating bath, and the other plating conditions are not particularly limited; optionally selected conditions may be applied. On completion of this stage, the formation of the conductor layer is completed.

Step B: In this step of forming a dielectric layer, the resin film with the lower electrode forming layer formed thereon is wound off from the first film reel; a dielectric layer 7 is formed on the lower electrode forming layer 6 as shown in FIG. 6(B); and further a conductor layer (an upper electrode forming layer 8) is continuously formed on the dielectric layer 7 to form a second film reel.

In the formation of the dielectric layer 7 in this step, the dielectric layer 7 is formed on the surface of the lower electrode forming layer 6 situated on the resin film 2, and hence the method for forming the dielectric layer 7 can hardly adopt a manufacturing method involving the application of high temperatures; accordingly, it is preferable to use either sputtering deposition or aerosol deposition mentioned above.

For the formation of the upper electrode forming layer 8, it is preferable to use either sputtering deposition or aerosol deposition. Also in the formation of the upper electrode forming layer 8, a manufacturing method involving the application of high temperatures cannot be adopted. Besides, the curing is as described above.

Step C: In this perforation step, the resin film with the dielectric layer 7 and the conductor layer (the upper electrode forming layer 8) formed thereon is wound off from the second film reel; and sprocket holes 9 are continuously formed in the two widthwise edge areas of the resin film to result in a state shown in FIG. 6(C); and the resin film is wound in a form of reel to form a third film reel. In the formation of the sprocket holes 9, it is preferable to apply such a blanking method with dies as described above.

Step D: In this step of forming solder ball land holes, the resin film with the sprocket holes 9 formed therein is wound off from the third film reel; and predetermined portions of the resin film are removed from the surface of the resin film to continuously form solder ball land holes 10 in the resin film as shown in FIG. 6(D), which is wound to form a fourth film reel.

Specifically, for the purpose of forming the solder ball land holes 10 from the resin film side as shown in FIG. 6(D), preferably the portions needing no processing are subjected to masking and the dry removal based on the sputtering method is applied. Although only the resin film in the portions needing the removal can also be chemically removed with a chemical reagent, it is preferable to apply a dry removal from the viewpoint of accuracy. However, it is most preferable to apply a chemical treatment with a chemical reagent in combination with the dry removal, for the purpose of removing the residual resin component, after the dry removal based on the sputtering method has been applied.

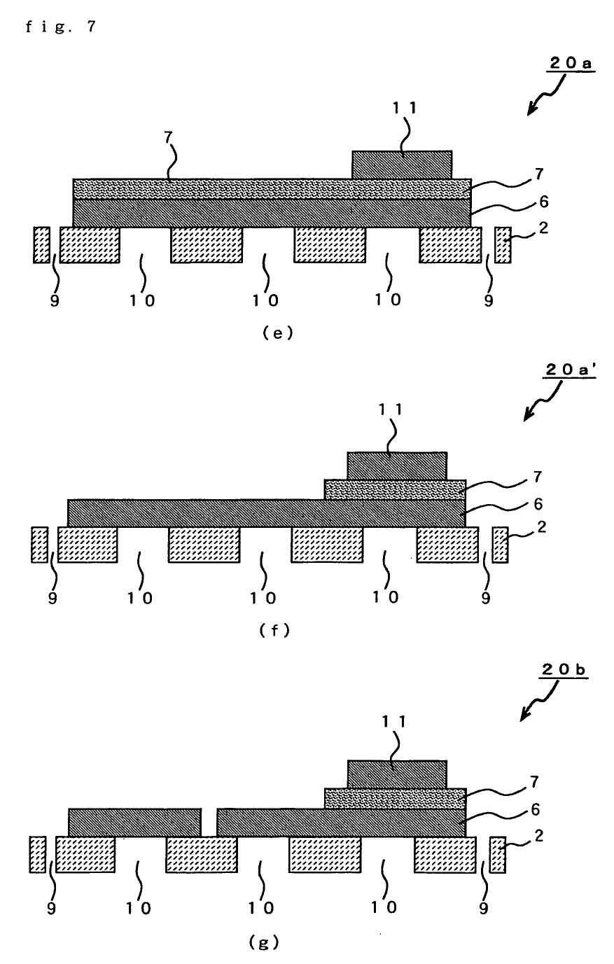

Step E: In this step of forming a capacitor circuit, the resin film is wound off from the fourth film reel; the upper electrode forming layer 8 is patterned to form the shape of an upper electrode circuit 11; the dielectric layer 7 is exposed in the portion other than the upper electrode circuit 11; the exposed portion of the dielectric layer 7 is removed; and the thus processed resin film is wound in a form of reel to form a film carrier tape 20a with a capacitor circuit, including solder ball land holes 10 and including, in the wiring pattern, a capacitor circuit (a structure having the dielectric layer 7 located between the upper electrode 11 and the lower electrode 12), as shown in FIG. 7(E).

On completion of such removal of the dielectric layer as described above, the dielectric layer portion in the vicinity of the end of the upper electrode tends to be damaged, and the end of the upper electrode circuit and the end of the lower electrode circuit tend to be short-circuited. Accordingly, it is preferable to adopt the same step of trimming the upper electrode as described above. It is to be noted that also in this case, this step of trimming the upper electrode can also be carried out simultaneously with the etching of the lower electrode to be described below.

In this stage, a step of forming the lower electrode circuit is adopted if needed, which step is an additional step to be carried out if needed in the method for manufacturing the film carrier tape with a capacitor circuit, and in which step the exposed portion of the dielectric layer 7 is removed and the lower electrode forming layer 6 is thus partially exposed to form a film carrier tape 20a′ with a capacitor circuit shown in FIG. 7(F). Further, the lower electrode forming layer 6 is patterned to form the lower electrode circuit 12, and thus to form a film carrier tape 20b with a capacitor circuit shown in FIG. 7(G).

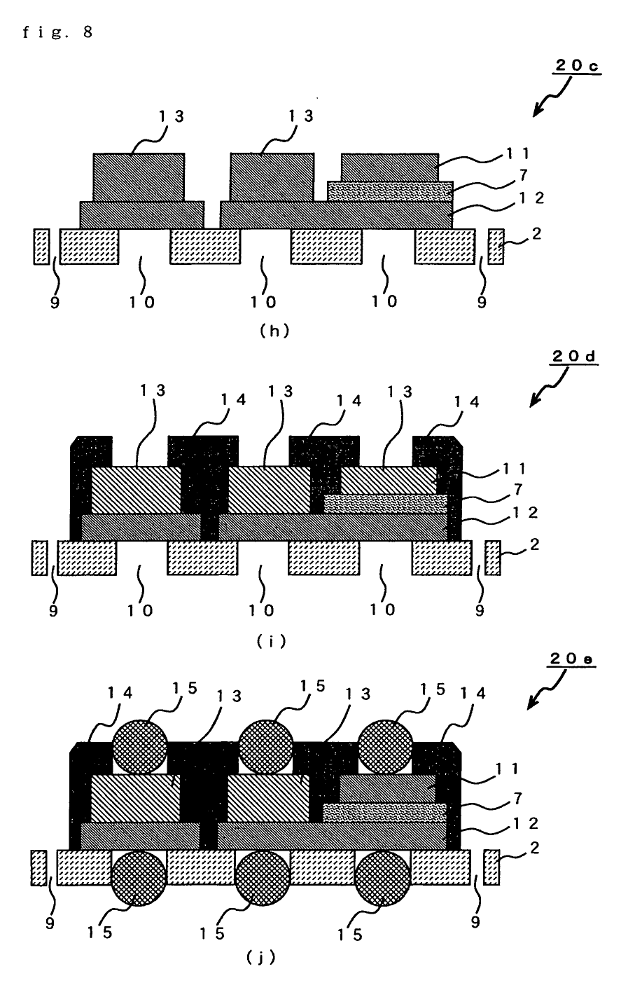

The method for manufacturing the film carrier tape with a capacitor circuit may further comprise a step of providing post electrodes 13 to be terminal pads on the wiring pattern which step is an additional step to be carried out if needed. The provision of the post electrodes 13 leads to a state of the film carrier tape 20c with a capacitor circuit shown in FIG. 8(H). This formation of the post electrodes is optional, and accordingly, the formation of the post electrodes is not necessary as the case may be, but illustration of such a case is omitted.

The method for manufacturing the film carrier tape with a capacitor circuit preferably comprises a step of providing a cover film 14 in such a way that the surface of the upper electrode 11 of the capacitor circuit and the other wiring patterns (the terminal pads are included as the case may be) of the capacitor circuit are partially exposed, and the exposed portions each serve as a solder ball land hole 10. The components, the formation method and the like of the cover film 14 are the same as in the first manufacturing method. FIG. 8(I) schematically shows the film carrier tape 20d with a capacitor circuit for the case where the cover film is formed.

On completion of the formation of the cover film 14 as described above, from the bottom of the solder ball land holes 10 in the resin film and the bottom of the solder ball land holes 10 in the cover film, any of the surface of the upper electrode 11, the surface of the lower electrode 12 and the surface of the post electrodes 13 is exposed. Accordingly, the method preferably comprises a step of providing an auxiliary metal layer 16 made of any of a gold-copper alloy layer, a gold-copper-silicon alloy layer, a nickel layer and a gold layer, unless the materials of the surface of the upper electrode, the surface of the lower electrode and the surface of the post electrodes are each any of a gold-copper alloy layer, a gold-copper-silicon alloy layer, a nickel layer and a gold layer. Among the accompanying drawings, the auxiliary metal layer 16 is depicted in FIG. 8(J).

The method for manufacturing the film carrier tape with a capacitor circuit according to the present invention further comprises a step of disposing a solder ball 15 in each of the solder ball land holes 10 in the resin film and the solder ball land holes 10 in the cover film. When the solder balls 15 are disposed in the solder ball land holes 10, the solder balls 15 can be held without fail by disposing the solder balls through the intermediary of a conductive adhesive. No particular constraint is imposed on the method for disposing the conductive adhesive. In a state that the solder balls 15 are disposed in such a way, there is obtained a film carrier tape 20e with a capacitor circuit capable of permitting surface mounting, as shown in FIG. 8(J).

<Surface-Mounted Film Carrier Tape with a Capacitor Circuit According to the Present Invention>

Surface-mounting of electronic components such as flip chips on the sites provided with solder balls in the above described film carrier tape with a capacitor circuit leads to formation of a lengthy surface-mounted film carrier tape with a capacitor circuit.

Preferably, the bonding of electronic components to the film carrier tape with a capacitor circuit is carried out in such a way that a lengthy surface-mounted film carrier tape with a capacitor circuit is obtained by adopting a method comprising continuously winding off the film carrier tape with a capacitor circuit in a form of reel and mounting electronic components by bonding at predetermined positions by means of a bonder device. In this bonding, no particular constraint is imposed on the heating conditions and the pressing conditions of the bonder device; in consideration of the strength of the electronic components to be bonded, there may be optionally selected such optimal conditions that permits optimal bonding. For example, for the purpose of improving the reliability of the bonding, it is preferable to adopt a variable loading scheme (with an initial load of 5 g/bump, and a final load of 30 g/bump) in which the bonding load is stepwise increased by applying ultrasonic waves while the bonding is being carried out. Among others, the application conditions of the ultrasonic waves are preferably such that the vibration amplitude of the chip bonding tool is set at 1 μm to 4 μm, and the ultrasonic wave application time is set at 200 ms to 350 ms. Additionally the bonding temperature is preferably such that the tool heating temperature on the side of the electronic components is set at 220° C. to 250° C., and the temperature of the work stage for mounting the film carrier tape with a capacitor circuit is set at room temperature. The bumps of the electronic components are also preferably subjected to necessary treatments such as coating of a conductive adhesive.

The electronic components as referred to herein as capable of being mounted include semiconductor chips and all other chip components, without any particular constraint imposed on such components. In other words, what is essential is the combination of the shape of the circuit formed on the film carrier tape with a capacitor circuit and the shape and others of the electrode of the electronic component to be mounted thereon; any electronic component can be mounted as long as it leads to a satisfactory accordance in shape. Accordingly, preferably used among these electronic components are flip chip components. No particular constraint is imposed on the constituent materials for the bump areas of these electronic components; optionally usable examples of such constituent materials include, for example, copper, a copper alloy, gold, aluminum and a solder, and it suffices that these materials are appropriately selected to be used in consideration of the bonding strength with the pad areas (solder balls) of the film carrier tape with a capacitor circuit.

The surface-mounted film carrier tape with a capacitor circuit in which surface mounting of electronic components has been completed is supplied in a form of tape, which is cut into individual product units according to the quantities to be used, these units being able to be used as embedded in the wiring substrates, or as bonded to other wiring substrates.

The above described film carrier tape with a capacitor circuit according to the present invention is provided with bumps (solder balls) both in the resin film and in the cover film; however, with the aid of the same technical concept as implemented above, it is easy to provide bumps (solder balls) only in one of these films.

The film carrier tape with a capacitor circuit according to the present invention is an article in which on a resin film made of polyimide, PET or the like, a capacitor circuit and circuit shapes such as terminal pads are optionally formed. Accordingly, it comes to be possible to supply, in a state of tape, a thin film decoupling capacitor made of a resin excellent in flexibility such as polyimide. Thus, it takes a form of tape, and can be wound in a form of reel, which facilitates handling at the time of transfer or the like. In addition, the market can be supplied with articles undergoing various processing degrees, reflecting the technical steps to be implemented by the users, such as a state in which a capacitor circuit is formed on the surface of a resin film, and a state in which a capacitor circuit and post electrodes are formed on the surface of a resin film. Furthermore, a surface-mounted film carrier tape with a capacitor circuit can be shipped in a form of reel obtained as follows: the surface-mounted film carrier tape with a capacitor circuit is obtained by surface mounting of components starting from a state in which a capacitor circuit, a cover film and the like are formed and solder balls are disposed on the surface of a resin film; and this surface-mounted state is converted into a form of reel.

Additionally, the manufacture of the film carrier tape with a capacitor circuit according to the present invention can adopt steps similar to those for conventional TAB products, and does not invoke the use of silicon substrates or the like. Furthermore, while the tape carrier is traveling in the various steps, formation of various coating films, formation of a dielectric layer in a low temperature region, etching and the like can also be continuously carried out; thus the manufacture of the film carrier tape concerned can suppress the manufacturing cost, and permits supplying a film carrier tape with a capacitor circuit excellent in industrial productivity, low in price, excellent in quality stability and having flexibility.

What is claimed is:

1. A film carrier tape with a capacitor circuit, comprising a wiring pattern on the surface of a resin film comprising a plurality of sprocket holes on each of the two edges,
wherein the resin film comprises solder ball land holes; and
the wiring pattern comprises a capacitor circuit having a structure in which a dielectric layer is disposed between an upper electrode and a lower electrode.

2. The film carrier tape with a capacitor circuit according to claim 1, wherein a cover film is provided in such a way that the surface of the upper electrode of the capacitor circuit and the other wiring patterns of the capacitor circuit are partially exposed, and the exposed portions each serve as a solder ball land hole.

3. The film carrier tape with a capacitor circuit according to claim 2, wherein the bottom of the solder ball land holes of the resin film and the bottom of the solder ball land holes formed in the cover film disposed on the opposite side of the resin film are each provided with an auxiliary metal layer made of any of a gold-copper alloy layer, a gold-copper-silicon alloy layer, a nickel layer and a gold layer, and these holes are each provided with a solder ball.

4. The film carrier tape with a capacitor circuit according to claim 2, wherein the cover film is formed by using a solder mask.

5. The film carrier tape with a capacitor circuit according to claim 1, wherein the wiring pattern is provided with post electrodes to be terminal pads.

6. The film carrier tape with a capacitor circuit according to claim 5, wherein a cover film is provided in such a way that the surface of the post electrodes and the surface of the upper electrode of the capacitor circuit are partially exposed, and the exposed portions each serve as a solder ball land hole.

7. The film carrier tape with a capacitor circuit according to claim 6, wherein the bottom of the solder ball land holes of the resin film and the bottom of the solder ball land holes formed in the cover film disposed on the opposite side of the resin film are each provided with an auxiliary metal layer made of any of a gold-copper alloy layer, a gold-copper-silicon alloy layer, a nickel layer and a gold layer, and these holes are each provided with a solder ball.

8. The film carrier tape with a capacitor circuit according to claim 6, wherein the cover film is formed by using a solder mask.

9. A surface-mounted film carrier tape with a capacitor circuit, obtained by surface-mounting electronic components on the film carrier tape with a capacitor circuit according to claim 7 provided with solder balls.

10. A method for surface-mounting electronic components on a film carrier tape with a capacitor circuit, the method comprising:
continuously winding off a film carrier tape with a capacitor circuit, in a form of reel, and mounting electronic components by bonding at predetermined positions by means of a bonder device.
